(19) United States
(12) Patent Application Publication
(10) Pub. No.: US 2025/0343417 A1
(43) Pub. Date: Nov. 6, 2025

(54) METHODS AND SYSTEMS FOR PROVIDING STABILITY TO AN ELECTRICITY GRID

(71) Applicant: Firmus Technologies Pty Ltd, Cremorne, Victoria (AU)

(72) Inventor: Jonathan LEVEE, Cremorne, Victoria (AU)

(21) Appl. No.: 19/126,452

(22) PCT Filed: Nov. 3, 2023
(86) PCT No.: PCT/AU2023/051114

§ 371 Date: May 1, 2025

(30) Foreign Application Priority Data
Nov. 3, 2022 (AU) 2022903285

(51) Int. Cl. H02J 3/24; H02J 3/00

(52) U.S. Cl. CPC H02J 3/241; H02J 3/004

(57) ABSTRACT

Embodiments generally relate to a computer-implemented method for adjusting an operation frequency of an electricity grid, the electricity grid electrically connecting to at least one grid stabilisation device. The method comprises, at a control device, obtaining from a frequency reader connected to the electricity grid the operation frequency of the electricity grid during an adjustment interval; determining a time derivative of the obtained operation frequency; determining a predicted future operation frequency based on the obtained operation frequency and the time derivative; determining a frequency difference between the predicted future operation frequency and a reference operation frequency; and instructing the at least one grid stabilisation device to change its collective operation power to adjust the operation frequency of the electricity grid.

### TECHNICAL FIELD

Described embodiments relate to methods and systems for providing stability to an electricity grid. In particular, embodiments relate to methods and systems for providing stability to an electricity grid in real-time.

### BACKGROUND

An electricity system operates at an operation frequency. The operation frequency needs to be within a safe frequency range or frequency band defined by a primary operation frequency and a frequency deviation for the electricity system to operate safely. This safe frequency range may be referred to as the Normal Operating Frequency Band (NOFB). For example, the primary operation frequency of the electricity system is 50 Hz in Australia, and the frequency deviation is 0.15 Hz. That means if the electricity system operates within the frequency band between 49.85 Hz and 50.15 Hz, it is safe for the supply side to generate electricity energy and for the load side to consume the electricity energy. The NOFB may be defined as between 49.85 and 50.15 HZ in this case.

An electricity system will have a supply side and a load side. The supply side refers to power supply systems such as power plants that generate or provide the electricity energy, while the load side refers to the devices that draw or consume the electricity energy generated by the supply side. The electricity system may also include batteries which store power, and which will act as a supply system when discharging and as a load when recharging. There is also an electricity transmission and distribution network between the supply side and the load side, referred to as the electricity grid or “grid”, which is designed to transmit and distribute the electricity energy generated by the supply side to the load side.

The operation frequency may fluctuate with the power of the supply side and/or the power of the load side. For example, the operation frequency of the electricity grid may drop due to a fault of an electric generator (i.e., loss of electricity supply) or may ramp up due to the start of an electric generator (i.e., increase of electricity supply). The operation frequency of the electricity grid may also drop due to connection of loads to the electricity grid (e.g., increase of load during peak hours) or may ramp up if the loads are disconnected from the electricity grid. If the fluctuation of the operation frequency goes beyond the NOFB, which is between 49.85 Hz and 50.15 Hz in Australia as set out above, it may cause damages to the supply side (for example, the generators in the power plants) or the load side (for example, electric equipment that consumes electricity). There is a need for a system and method for providing grid stabilisation such as by adjusting the operation frequency of the electricity grid in response to the frequency fluctuation, particularly, outside the NOFB, in real time to make sure the electricity system operates safely.

It is desired to address or ameliorate some of the disadvantages associated with prior methods and systems for providing stability to an electricity grid, or at least to provide a useful alternative thereto.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

Some embodiments relate to a computer-implemented method for adjusting an operation frequency of an electricity grid, the electricity grid electrically connecting to at least one grid stabilisation device, the method comprising, at a control device:
obtaining from a frequency reader connected to the electricity grid the operation frequency of the electricity grid during an adjustment interval;
determining a time derivative of the obtained operation frequency;
determining a predicted future operation frequency based on the obtained operation frequency and the time derivative;
determining a frequency difference between the predicted future operation frequency and a reference operation frequency; and
instructing the at least one grid stabilisation device to change its collective operation power to adjust the operation frequency of the electricity grid.

Some embodiments further comprise determining a prediction error, the prediction error being a difference between the obtained operation frequency and a previously predicted operation frequency.

In some embodiments, determining a predicted future operation frequency comprises adjusting the predicted future operation frequency by the prediction error.

In some embodiments, the at least one grid stabilisation device comprises at least one load device.

According to some embodiments, instructing the at least one grid stabilisation device to change its collective operation power comprises instructing the at least one load device to increase the amount of power it is drawing from the grid.

In some embodiments, instructing the at least one grid stabilisation device to change its collective operation power comprises instructing the at least one load device to decrease the amount of power it is drawing from the grid.

According to some embodiments, the at least one grid stabilisation device comprises at least one supply device.

According to some embodiments, instructing the at least one grid stabilisation device to change its collective operation power comprises instructing the at least one supply device to increase the amount of power it is supplying to the grid.

In some embodiments, instructing the at least one grid stabilisation device to change its collective operation power comprises instructing the at least one supply device to decrease the amount of power it is supplying to the grid.

Some embodiments relate to a computer-implemented method for adjusting an operation frequency of an electricity grid, the electricity grid electrically connecting to at least one grid stabilisation device, the method comprising, at a control device:
obtaining from a frequency reader connected to the electricity grid the operation frequency of the electricity grid during an adjustment interval;
determining a frequency difference between the obtained operation frequency and a reference operation frequency; and
instructing the at least one grid stabilisation device to change its collective operation power to adjust the operation frequency of the electricity grid by altering the power being supplied by the at least one grid stabilisation device to the grid.

In some embodiments, the at least one grid stabilisation device comprises at least one supply device.

In some embodiments, the at least one grid stabilisation device comprises a power generation device.

According to some embodiments, the at least one grid stabilisation device comprises at least one power storage device.

In some embodiments, the at least one grid stabilisation device comprises a battery.

According to some embodiments, instructing the at least one grid stabilisation device to change its collective operation power comprises instructing the at least one supply device to increase the amount of power it is supplying to the grid.

According to some embodiments, instructing the at least one grid stabilisation device to change its collective operation power comprises instructing the at least one supply device to decrease the amount of power it is supplying to the grid.

In some embodiments, the at least one grid stabilisation device is a non-rotor based device. In some embodiments, the at least one grid stabilisation device is an inverter-based device. According to some embodiments, the at least one grid stabilisation device comprises a battery. According to some embodiments, the at least one grid stabilisation device is fast-acting. In some embodiments, the at least one grid stabilisation device is dynamic.

Some embodiments relate to an electric load network for adjusting an operation frequency of an electricity grid in real time, the electric load network comprising:
a set of grid stabilisation devices;
a control device that is connected to the set of grid stabilisation devices;
a frequency reader that is connected to the control device, the frequency reader being configured to read from the electricity grid the operation frequency of the electricity grid during an adjustment interval;
wherein the control device is configured to
obtain from the frequency reader the operation frequency of the electricity grid during an adjustment interval;
determine a time derivative of the obtained operation frequency;
determine a predicted future operation frequency based on the obtained operation frequency and the time derivative;
determine, a frequency difference between the predicted future operation frequency and a reference operation frequency; and
instruct the grid stabilisation devices to change their collective operation power to adjust the operation frequency of the electricity grid.

Some embodiments relate to an electric load network for adjusting an operation frequency of an electricity grid in real time, the electric load network comprising:
a set of grid stabilisation devices;
a control device that is connected to the set of grid stabilisation devices;
a frequency reader that is connected to the control device, the frequency reader being configured to read from the electricity grid the operation frequency of the electricity grid during an adjustment interval;
wherein the control device is configured to
obtain from the frequency reader the operation frequency of the electricity grid during an adjustment interval;
determine a frequency difference between the obtained operation frequency and a reference operation frequency; and
instruct the grid stabilisation devices to change their collective operation power to adjust the operation frequency of the electricity grid by altering the power being supplied by the at least one grid stabilisation device to the grid.

Some embodiments relate to a control device for adjusting an operation frequency of an electricity grid in real time, the control device comprising:
a processor;
a bus connected to the processor;
a computer-readable memory connected to the bus, the computer-readable memory being configured to store a set of computer-readable instructions;
a first communication interface connected to the bus, the first communication interface being configured to connect to a set of computing devices; and
a second communication interface connected to the bus, the second communication interface being configured to connect to a frequency reader;
wherein the processor is configured to read the set of the computer-readable instructions from the computer-readable memory and perform the method as defined in some other embodiments.

Some embodiments relate to a non-transitory computer-readable medium storing a set of instructions that when executed cause a control device to perform the method as defined in some other embodiments.

### BRIEF DESCRIPTION OF DRAWINGS

Notwithstanding any other forms which may fall within the scope of the present disclosure, embodiments will now be described, by way of example only, with reference to the accompanying drawings, in which:

FIG. 1 illustrates an electricity system according to some embodiments;

FIG. 2 illustrates a grid stabilisation network in accordance with some embodiments;

FIG. 3A illustrates a method performed by a control device in accordance with some embodiments;

FIG. 3B illustrates an alternative method performed by a control device in accordance with some embodiments;

FIG. 4 is a graph illustrating the fluctuation of the operation power of a set of load devices in a grid stabilisation network in response to the fluctuation of the operation frequency of the electricity grid in accordance with some embodiments;

FIG. 5 is a graph illustrating the fluctuation of the operation power of a set of load devices in a grid stabilisation network in response to the fluctuation of the operation frequency of the electricity grid in accordance with some embodiments; and

FIG. 6 illustrates an exemplary structure of the control device in accordance with some embodiments.

It should be noted in the accompanying drawings and description below that like or the same reference numerals in different drawings denote the same or similar elements.

### DESCRIPTION OF EMBODIMENTS

Described embodiments relate to methods and systems for providing stability to an electricity grid. In particular, embodiments relate to methods and systems for providing stability to an electricity grid in real-time.

Devices within an electricity system operate at an operation frequency, which needs to be within a safe frequency range in order for the system to function correctly. The operation frequency of an electricity system may fluctuate due to changes in the load being consumed or drawn or the supply being generated or otherwise delivered to the grid. There is a need for a system and method for adjusting the operation frequency of the electricity grid in response to the frequency fluctuation, and thus providing stability to the grid. In particular, there is a need to keep the operation frequency of an electricity system within a predetermined frequency range to make sure the electricity system operates safely.

Described embodiments relate to methods and systems that use a grid stabilisation network to adjust the frequency of an electricity grid. The grid stabilisation network comprises one or more load devices and/or supply devices that can be operated to increase or decrease the power being delivered or consumed by the grid stabilisation network, in order to effect a frequency adjustment. The frequency adjustment may be delivered in response to a frequency measurement taken of the operation frequency of the electricity grid. The grid stabilisation network may operate to perform primary frequency response functions such as synthetically produce inertia in the electricity grid, and/or secondary frequency response functions which may be contingency services such as frequency stabilisation, in some embodiments. Inertia on an energy grid refers to the physical property of the grid that enables it to maintain a stable frequency and respond to changes in electricity supply and demand. However, the transition from non-renewable, synchronous generation to renewable, inverter-based generation is causing a lack of inertia in the grid. Inertia is critical for grid stability, and a grid with low inertia is often referred to as a weak grid.

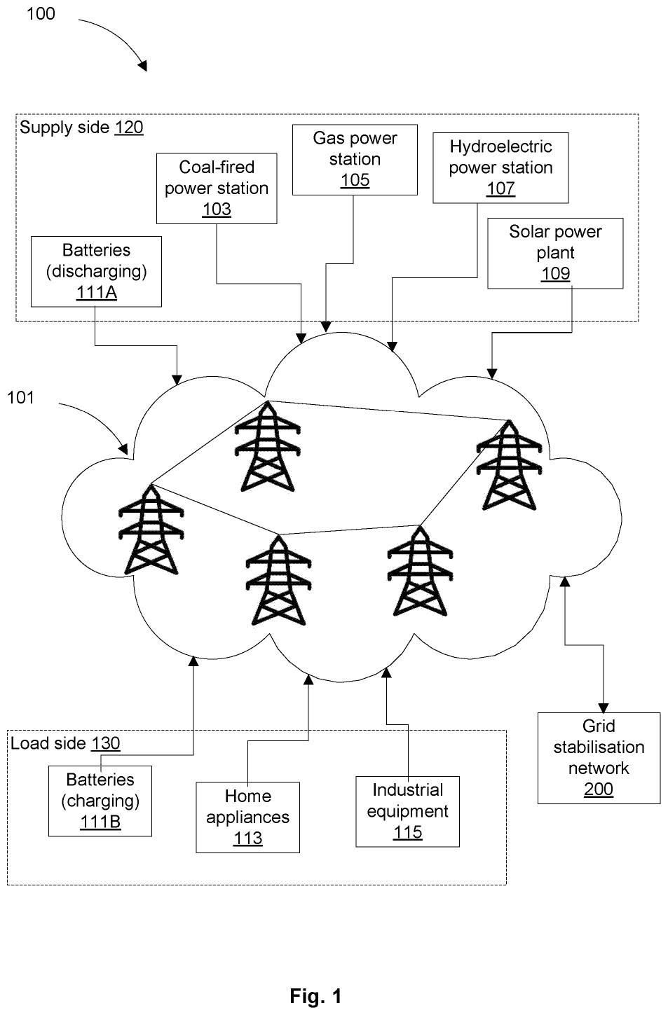

FIG. 1 illustrates an electricity system 100 according to some embodiments.

As shown in FIG. 1, the electricity system 100 includes supply and load devices. The supply side 120 may include power supply systems or power stations, which may include one or more synchronous generators or rotor-based generators such as one or more of a coal-fired power station 103, a gas power station 105, or a hydroelectric power station 107, for example. The supply side 120 of the electricity system 100 may also or alternatively include invertor-based supply systems or power stations, which may be known as invertor-based resources (IBRs), and which may include solar power plants 109as well as wind power plants, batteries or battery energy storage systems (BESS) 111, for example. Batteries 111 may include uninterruptable power supply (UPS) systems in some embodiments. The supply side 120 of the electricity system 100 can also include other forms of power supply systems or power stations that are able to generate or otherwise supply electrical energy to the grid without departing from the scope of the present disclosure.

The electricity system 100 further includes an electricity transmission and distribution network 101 (i.e., the electricity grid or the “grid”) electrically connected to the supply systems and power stations on the supply side 120. The supply side 120 of the electricity system 100 generates electrical energy and supplies the electrical energy into the electricity grid 101. The electricity grid 101 transmits and distributes the electrical energy generated from the supply side 120 to the load side 130 of the electricity system 100.

As shown in FIG. 1, the load side 130 of the electricity system 100 includes different types of loads that are electrically connected to the electricity grid 101 to consume the electrical energy transmitted and distributed by the electricity grid 101. The loads can include home appliances 113 for domestic use, such as televisions, washing machines, computing devices and refrigerators, for example. The loads can additionally or alternatively include industrial equipment 115 for industrial use, such as a smelting furnace in an aluminium smelting plant, for example. In some embodiments, the loads may include one or more charging batteries 111. Batteries 111 may include uninterruptable power supply (UPS) systems in some embodiments. The load side 130 of the electricity system 100 can also include other forms of loads without departing from the scope of the present disclosure.

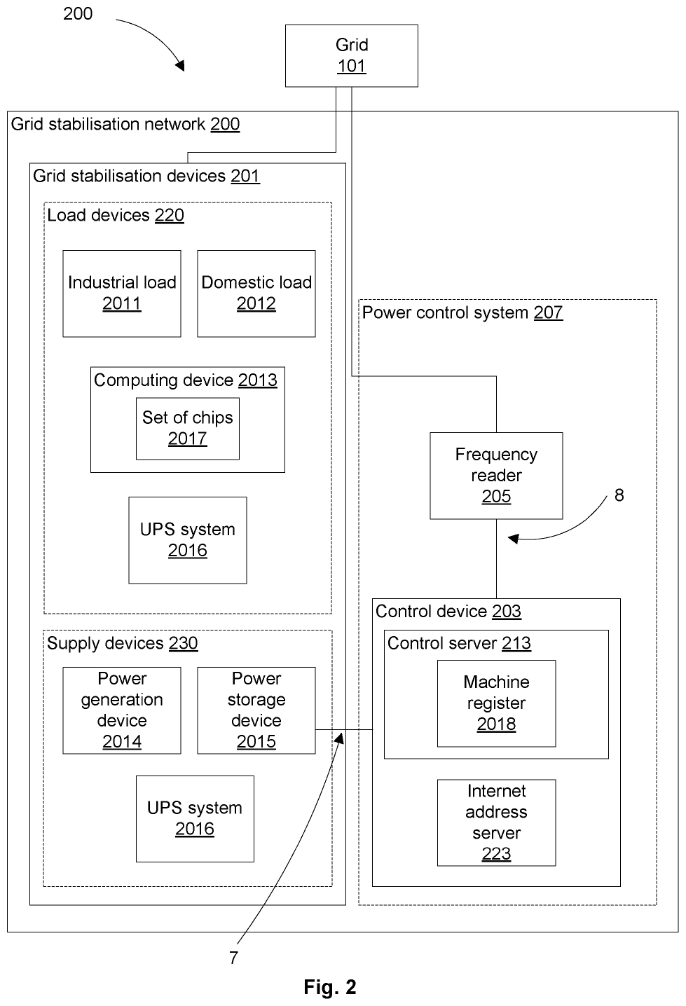

Electricity system 100 further includes a grid stabilisation network 200, as described in further detail below with respect to FIG. 2. Grid stabilisation network 200 may include one or more load devices and/or one or more supply devices, according to some embodiments. In some embodiments, grid stabilisation network 200 may be configurable to act as either a load device or a supply device to either consume power from or deliver power to electricity grid 101. Grid stabilisation network 200 may be configured to automatically adjust the amount of power being consumed from or delivered to the electricity grid 101 in order to perform frequency adjustment functions.

FIG. 2 illustrates the grid stabilisation network 200 for adjusting the operation frequency of the electricity grid 101, according to some embodiments.

As shown in FIG. 2, the grid stabilisation network 200 includes one or more grid stabilisation devices 201. In the illustrated embodiment, the grid stabilisation devices 201 include six grid stabilisation devices labelled 2011, 2012, 2013, 2014, 2015 and 2016. Although there are six grid stabilisation devices 2011, 2012, 2013, 2014, 2015 and 2016 shown in FIG. 2, the set of grid stabilisation devices 201 may include more or less grid stabilisation devices.

According to some embodiments, grid stabilisation devices 201 may comprise any load or supply device that is sufficiently fast acting and dynamic, where a fast acting device is one that can alter its operation within a predetermined time limit, and a dynamic device is one that can be adjusted in its degree of operation on a range from non-operational to fully operational. For example, according to some embodiments, a fast acting device may be a device that can alter its operation within one minute of being instructed to do so. In some embodiments, a fast acting device may be a device that can alter its operation within 6 seconds of being instructed to do so. In some embodiments, a fast acting device may be a device that can alter its operation within 1 second of being instructed to do so. According to some embodiments, a dynamic device may be one that has an adjustable power profile such that it has configurable power settings between 0% and 100%.

Examples of devices that might be considered fast-acting include non-rotor-based devices, such as non-rotor-based power generation or supply devices. These may include batteries, UPS systems, and inverter based devices such as inverter based power generation devices, which may include solar power stations.

Devices that are not fast-acting may include devices comprising rotating members, such as rotors. Rotating members have inertia which can be difficult to overcome, especially when the member has a large mass. Examples of devices that might not be considered fast-acting include rotor-based power generation devices such as coal-fired power stations and gas power stations. These devices are generally controlled using governors on the prime mover, turbine or generator elements, but can take a significant amount of time to start up or stop.

In terms of their response to changes in the electrical grid, synchronous rotor-based generators are not inherently fast-acting in the way that some power electronics are. They cannot instantaneously adjust their speed or output in response to rapid changes in the grid. Instead, the stability and response of these generators are often managed by the governing systems that control the input mechanical power.

However, they are capable of contributing to grid stability. One way they do this is through their inherent ability to contribute to grid inertia. The rotational inertia of the generator contributes to the overall inertia of the grid, which can act as a buffer against rapid changes in frequency. This inertia allows synchronous generators to support frequency control, which is critical for the stability of the power system.

Fast-acting response to disturbances for synchronous machines is generally facilitated by Automatic Voltage Regulators (AVRs) and governors for controlling active and reactive power. These control systems react to deviations in voltage and frequency, and adjust the field excitation and mechanical power input to the generator to stabilize its output.

For a synchronous generator to contribute to the rapid stabilization of the grid, particularly in systems with high penetration of renewable sources, additional technologies such as Flexible AC Transmission Systems (FACTS), Static VAR Compensators (SVCs), and Battery Energy Storage Systems (BESS) may be integrated. These technologies can act much faster than traditional generation equipment to mitigate transient phenomena and ensure stable grid operation. In some embodiments, such technologies may be used as grid stabilisation devices.

Each of the set of the grid stabilisation devices 201 may either supply or draw an individual operation power to or from the electricity grid 101. The sum of the individual device powers of the grid stabilisation devices 201 is referred to as a collective operation power.

Supply devices 230 may include power generation devices 2014 and/or power storage devices 2015. According to some embodiments, supply devices 230 may include inverter-based resources (IBRs), such as photovoltaic cells, wind turbines, and batteries. For example, supply devices may include uninterruptable power supply (UPS) systems 2016 in some embodiments, when the batteries of such systems are discharging.

Where the grid stabilisation devices 201 comprise UPS systems 2016, the UPS system 2016 may form part of a back-up power system for a power drawing facility such as a data centre, for example. Each UPS system 2016 may comprise one or more batteries and control systems, and may be designed to supply power to a facility in the case of a disruption to the main power supply, for example. UPS systems 2016 may be used to supply power to a facility in the case of a disruption to the main power supply for the time between the loss of power to a time at which a secondary power source can be provided, such as the time it takes a diesel generator to start up and start supplying power, for example. Due to the minimum autonomy of a UPS battery generally being much higher than the time for which such a battery would be required to supply power in case of a disruption, these batteries can be used for other power supply purposes while they are not needed for back-up power as described. For example, a UPS system may comprise a Lithium-Ion battery system capable of providing 2 MW for 5 minutes or 166 kW/h at battery termination voltage. However, the site may only require 1 minute of UPS backup and as such, even once full load is connected, there may be 4 minutes of latent battery capacity within each system, or 133 kW/h. This additional capacity can be leveraged to provide grid stabilisation services.

According to some embodiments, supply devices 230 such as UPS systems 2016 may be modified or specifically configured to improve their performance as grid stabilisation devices 201. According to some embodiments, hardware constraints of supply devices 230 may be mitigated or removed to allow them to provide additional services. For example, governors may be removed from batteries acting as supply devices 230 to allow for bidirectional frequency support, which would allow the batteries to charge more quickly. Specifically, the UPS systems 2016 may be modified to provide bi-directional power flow via their input rectifier. By being configured to both charge and discharge in a fast-acting way, UPS systems 2016 and other battery based supply devices 230 can be configured to act as both supply devices 230 and load devices 220.

Typically batteries charge slower than they discharge. In the stock UPS battery specification, discharging is 5 minutes, but charging time is 3 hours. This is to extend battery life, since charging or absorbing power is not part of the primary design functionality of this battery. This needs to be changed to perform both bi-directional FCAS, being both Raise and Lower FCAS services.

The charge time constraint is in the governor of the UPS. According to some embodiments, the Battery Management System of batteries acting as grid stabilisation devices 201 can be configured to allow for the batteries to charge or absorb energy at the same rate as they discharges or injects energy, allowing such batteries to participate in the fast and ultra-fast Lower FCAS services, as well as Raise FCAS services.

Grid stabilisation devices 201 may additionally or alternatively include one or more load devices 220. Load devices 220 may include industrial loads 2011, domestic loads 2012, or computing devices 2013 such as computers and/or servers, in some embodiments. Load devices 220 may additionally include uninterruptable power supply (UPS) systems 2016 in some embodiments, when the batteries of such systems are charging. Where the grid stabilisation devices 201 comprise computing devices 2013, the set of computing devices 2013 may be interconnected through communication links. The communication links may be physical links or logical links or a combination of physical links and logical links. The communication links may operate under a network communication protocol to communicatively connect the set of computing devices. The communication protocol may include cellular network communication protocols (for example, 3G/4G/5G communication protocols), Internet/Ethernet communication protocols (for example, TCP/IP protocol stack), Wireless Local Area Network (for example, IEEE 802.11 technical standards), or a combination of the aforementioned protocols or technical standards. The communication protocol can be other communication protocols without departing from the scope of the present disclosure.

The set of computing devices 2013 may be configured to electrically connect to the electricity grid 101 to be powered by the electricity grid 101 in order to perform the one or more computing tasks. The set of computing devices 2013 can be, for example, high-performance computers in a data centre or a cloud computing network.

The grid stabilisation network 200 further includes a control device 203 that is communicatively connected to the set of grid stabilisation devices 201 through a communication link 7 between the control device 203 and the set of grid stabilisation devices 201. Grid stabilisation devices 201 may be located between grid 101 control device 203, such that control device 203 is configured to control “behind the grid” or “behind the meter” services. Control device 203 may be configured to control devices local to control device 203.

The terms “behind the meter” and “behind the grid” generally refer to the location and operational domain of electrical equipment, like grid stability devices or inverters, in relation to the utility meter, which measures the flow of electricity for billing purposes.

Behind the Meter (BTM) refers to energy systems that are installed on the customer's side of the utility meter. These systems can include solar panels, battery storage, grid stability devices, inverters, and energy management systems. BTM installations are primarily intended to serve the energy needs of the customer's site. They can reduce the amount of electricity drawn from the grid, thereby lowering the utility bill. They can provide backup power during grid outages and enhance energy resilience. They can also potentially participate in demand response programs or provide ancillary services to the grid with proper arrangements. Any excess energy produced by BTM devices can be exported to the grid, often resulting in a credit to the customer (e.g., through net metering). BTM devices or systems are often for private use and are physically located on the customer's premises.

Behind the Grid refers to equipment that is operating on the distribution side of the electrical grid, which is downstream of the transmission grid but still before the end-user's meter. This can refer to equipment that is used by the utility or a third-party to support the distribution network's operation; systems that are meant to improve the quality or reliability of power before it reaches the customer's meter; and/or resources that may not necessarily be directly visible or controlled by the end-user but still affect their power supply and quality. Behind the Grid equipment is often part of the distribution system and impacts the customer indirectly.

Described embodiments typically allow private “behind the meter” assets to inject excess energy into the grid (supply), or absorb energy (load) to help manage frequency and grid stability. According to some embodiments, the described systems may comprise distribution network assets located behind the grid.

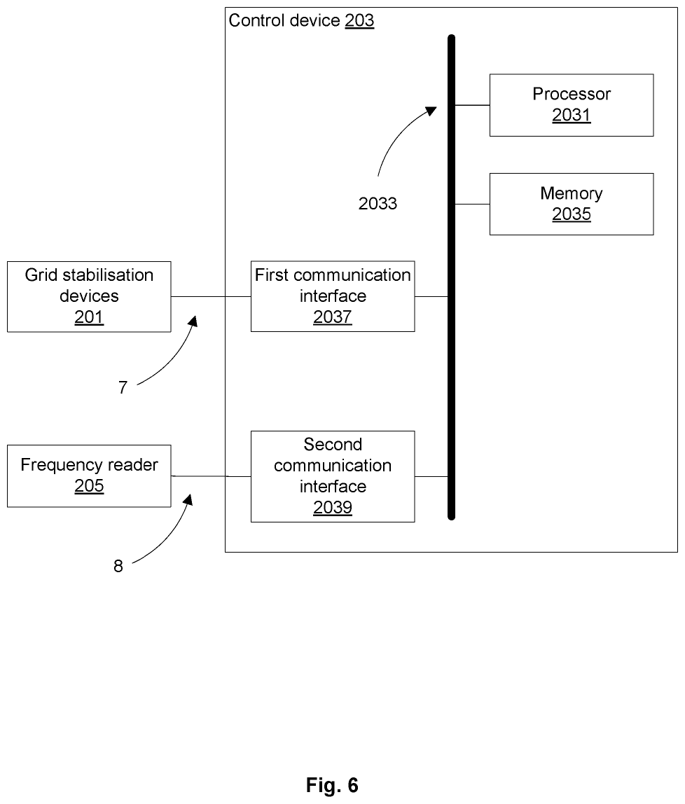

The communication link 7 can be a physical link or a logical link or a combination of a physical link and a logical link. The communication link 7 may operate under a network communication protocol to communicatively connect the control device 203 to the set of grid stabilisation devices 201. The communication protocol may include cellular network communication protocols (for example, 3G/4G/5G communication protocols), Internet/Ethernet communication protocols (for example, TCP/IP protocol stack including Transmission Control Protocol (TCP) and/or User Datagram Protocol (UDP)), Wireless Local Area Network (for example, IEEE 802.11 technical standards), or a combination of the aforementioned protocols or technical standards. The communication protocol can be other communication protocols without departing from the scope of the present disclosure. The control device 203 can be a standalone server. The control device 203 can also be a server stack including multiple physical or logical servers communicatively connected to each other without departing from the scope of the present disclosure. As an example, the control device 203 in FIG. 2 is a server stack including a control server 213 and an Internet address server 223. As another example, the control device 203 may be a standalone server with the functionalities of the both the control server 213 and the Internet address server 223. An exemplary structure of the control device 203 as a standalone server is described below with reference to FIG. 6.

The grid stabilisation network 200 further includes a frequency reader 205 that is communicatively connected to the control device 203 through a communication link 8. Frequency reader 205 may comprise a programmable logic controller (PLC) that is specific to electrical engineering and electrical hardware. For example, the frequency reader 205 may comprise a Schweitzer Engineering Laboratories (SEL) Axion device.

The communication link 8 can be a physical link or a logical link or a combination of a physical link and a logical link. The communication link 8 may operate under a network communication protocol to communicatively connect the control device 203 to the set of grid stabilisation devices 201. The communication protocol may include cellular network communication protocols (for example, 3G/4G/5G communication protocols), Internet/Ethernet communication protocols (for example, TCP/IP protocol stack), Wireless Local Area Network (for example, IEEE 802.11 technical standards), or a combination of the aforementioned protocols or technical standards. The communication link 8 can also operate under a data communication protocol designed to communicatively connect industrial or computing devices. The data communication protocol may include Modbus protocol, RS232 serial data communication protocol, DB25. parallel communicating protocol, USB protocol, etc. The communication protocol can also be other communication protocols without departing from the scope of the present disclosure.

According to some embodiments, control device 203 and frequency reader 205 may be integrated within a power control system 207. In some alternative embodiments, control device 203 and frequency reader 205 may be independent devices. Where control device 203 and frequency reader 205 are integrated within a power control system 207, the power control system 207 may include other components, such as a data recorder, site power reader or test signal generator, for example (not shown). The data recorder may be a high speed data recorder and may be configured to record the high speed data of any response provided by grid stabilisation network 200. The data recorder may be a requirement for compliance purposes in some cases. The site power reader may be configured to measure the site power, which may be measured in Watts, for example, and may measure the power supplied or consumed by the grid stabilisation devices 201. The test signal generator may be used to generate test frequency signals to use as a reference, in some embodiments.

The frequency reader 205 is configured to read from the electricity grid 101 the operation frequency of the electricity grid 101 during an adjustment interval. The adjustment interval may be an interval during which grid stabilisation network 200 is configured to adjust the operation frequency of the electricity grid 101. The adjustment interval may be around 50 milliseconds in some embodiments. According to some embodiments, the adjustment interval may be below 10 milliseconds. According to some embodiments, the adjustment interval may be between 10 milliseconds and 100 milliseconds. In some embodiments, the adjustment interval may be between 30 milliseconds and 800 milliseconds. During the adjustment interval, the control device 203 is configured to perform a method 300 for adjusting the operation frequency of the electricity grid 101 in real time or near to real time. The control device 203 may also be configured to perform other method steps described in the present disclosure. If the control device 203 is a standalone server, these method steps may be performed at the control device 203. If the control device 203 is a server stack including, for example, the control server 213 and the Internet address server 223, as shown in FIG. 2, the performing of these method steps may be distributed to the control server 213 and/or the Internet address server 223 without departing from the scope of the present disclosure. Further, for easy description, one or more particular steps may be described in the present disclosure as being performed at one of the control server 213 and the Internet address server 223. Such description, however, does not exclude the scenario where the particular one or more steps are performed at the other one of the control server 213 and the Internet address server 223.

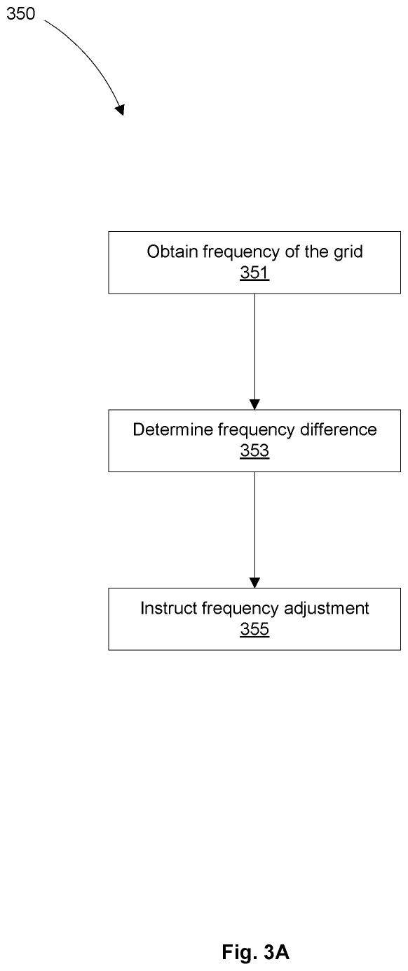

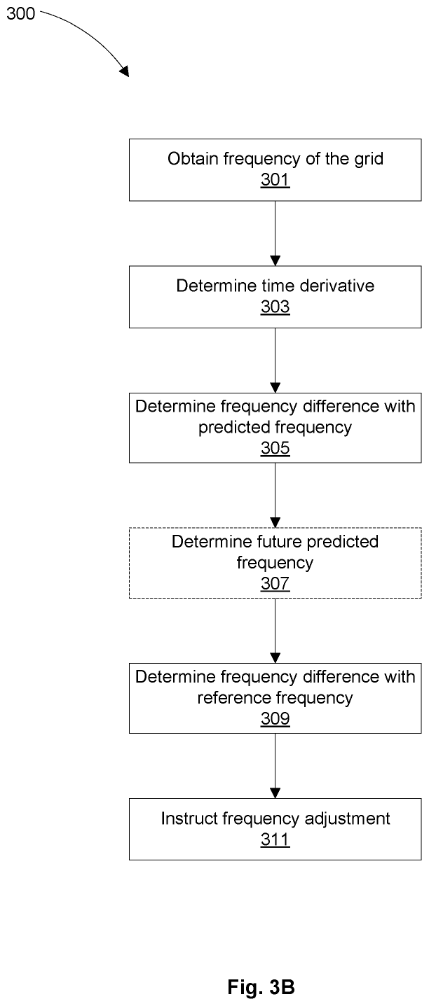

FIG. 3A illustrates the method 350 performed by the control device 203 in accordance with some embodiments. According to some embodiments, method 350 may be performed periodically. For example, method 350 may be performed approximately every 50 milliseconds.

In some embodiments, method 350 may be performed at an interval between every 10 milliseconds and every 100 milliseconds.

As shown in FIG. 3A, at step 351, the control device 203 obtains from the frequency reader 205 an operation frequency fₙ of the electricity grid 101 during an adjustment interval or time n. Specifically, the operation frequency fₙ read by the frequency reader 205 is sent from the frequency reader 205 to the control device 203 via the communication link 8. The operation frequency fₙ for each time n may be stored in a memory location for later retrieval.

At step 353, the control device 203 determines a frequency difference between the obtained operation frequency fₙ and a reference operation frequency f_{ref}. The reference operation frequency f_{ref} may be read from a memory storage location in some embodiments. The reference operation frequency f_{ref} may be the primary operation frequency of the electricity grid 101, which may be, for example, 50 Hz in Australia. According to some embodiments, the reference operation frequency f_{ref} may be defined by a range of frequencies, such as by a lower limit and an upper limit of a frequency range which may be an operation frequency range, for example. For example, the lower limit of the frequency band, or the minimum operation frequency of the electricity grid 101, may be 49.85 Hz in Australia. The upper limit of the frequency band, or the maximum operation frequency of the electricity grid 101, may be 50.15 Hz in Australia. Where the reference operation frequency f_{ref} is defined by a range or band of frequencies, the difference between the obtained operation frequency fₙ and a reference operation frequency f_{ref} may be the smaller of the difference between the obtained operation frequency fₙ and the upper limit of the reference operation frequency f_{ref}, and the difference between the obtained operation frequency fₙ and the lower limit of the reference operation frequency f_{ref}. In reality, the operation frequency of the electricity grid 101 almost always fluctuates over time and does not stay at a particular frequency consistently. Therefore, there is almost always a frequency difference between the reference operation frequency and the operation frequency during a particular adjustment interval.

At step 355, the control device 203 instructs the set of grid stabilisation devices 201 to change the collective operation power of the set of grid stabilisation devices 201 based on the determined frequency difference to adjust the operation frequency of the electricity grid.

For example, when the frequency difference indicates the operation frequency is below the reference operation frequency, which means the operation frequency needs to be raised for safety purposes, the control device 203 sends a first command to the set of the grid stabilisation devices 201 instructing the set of grid stabilisation devices 201 to either lower the collective operation power drawn by the grid stabilisation devices 201, or to increase the collective operation power provided by the grid stabilisation devices 201. Where the grid stabilisation devices 201 comprise load devices 220, the control device 203 may issue a command to the grid stabilisation devices 201 that are load devices 220 to lower the collective operation power which they draw from the grid. Where the grid stabilisation devices 201 comprise supply devices 230, the control device 203 may issue a command to the grid stabilisation devices 201 that are supply devices 230 to increase the collective operation power which they supply to the grid.

On the other hand, when the frequency difference indicates the operation frequency is above the reference operation frequency, which means the operation frequency needs to be lowered for safety purposes, the control device 203 sends a second command to the set of grid stabilisation devices 201 instructing the set of grid stabilisation devices 201 to either raise the collective operation power drawn by the grid stabilisation devices 201, or to lower the collective operation power provided by the grid stabilisation devices 201. Where the grid stabilisation devices 201 comprise load devices 220, the control device 203 may issue a command to the grid stabilisation devices 201 that are load devices 220 to raise the collective operation power which they draw from the grid. Where the grid stabilisation devices 201 comprise supply devices 230, the control device 203 may issue a command to the grid stabilisation devices 201 that are supply devices 230 to lower the collective operation power which they supply to the grid.

FIG. 3B illustrates an alternative method 300 performed by the control device 203 according to some embodiments.

As shown in FIG. 3, at step 301, the control device 203 obtains from the frequency reader 205 an operation frequency fₙ of the electricity grid 101 during an adjustment interval or time n. Specifically, the operation frequency fₙ read by the frequency reader 205 is sent from the frequency reader 205 to the control device 203 via the communication link 8. The operation frequency fₙ for each time n may be stored in a memory location for later retrieval.

At step 303, the control device 203 determines a time derivative

$$\frac{{df}_{n}}{dt}$$

of the operation frequency, being the rate of change of the operation frequency. The control device 203 may calculate the time derivative based on a difference between the operation frequency fₙ at time n and the operation frequency fₙ₋₁ at time n−1. According to some embodiments, time n−1 may correspond to a time during a previous adjustment interval, which may be the adjustment interval directly preceding the adjustment interval at time n. In some embodiments, the time derivative or rate of change of the operation frequency may be determined based on any two or more measurements of the operation frequency taken at different points in time. The time derivative may be an average rate of change of the operation frequency over a time period, for example.

Optionally, at step 305, the control device 203 determines a corrective factor to be applied to the predicted frequency. The corrective factor may be a prediction error or the difference between the operation frequency fₙ obtained at step 301, and a previously predicted frequency f′ₙ. Previously predicted frequency f′ₙ may have been predicted during a previous iteration of method 300 as may have been performed at time n−1. The determined difference (f′ₙ−fₙ) may correspond to an error in the last prediction, and can be used as a corrective factor in the next prediction. Using the corrective factor as determined at step 305 may reduce the chance of the predicted frequency value determined at step 307 from diverging with the actual frequency over time. This may be particularly useful in periods of high volatility, when predictions may have a high degree of error.

At step 307, the control device 203 determines a predicted operation frequency f′ₙ₊₁ at time n+1, based on the operation frequency obtained at step 301, the time derivative calculated at step 303 and optionally on the error calculated at step 305. According to some embodiments, time n+1 may correspond to a time during a future adjustment interval, which may be the adjustment interval directly following the adjustment interval at time n. Where Δn is the time period between the current time n and the time of the next adjustment interval n+1, the predicted operation frequency may be determined using the equation:

$${f}_{n + 1}^{′} = {f}_{n} + {K}_{D} \frac{{df}_{n}}{dt} ( Δ t ) + {K}_{E} ( {f}_{n}^{′} - {f}_{n} )$$

where K_{D} is a differential coefficient, and K_{E} is an error coefficient. The coefficients K_{D} and K_{E} may be tuned or trained for different market conditions. For example, machine learning or AI tools may be used. Machine learning or AI models may be trained on past market conditions to allow appropriate coefficients K_{D} and K_{E} to be generated. In some alternative embodiments, coefficients K_{D} and K_{E} may be assigned binary values of 0 or 1 to turn the prediction and correction on or off. For example, where both coefficients are assigned the value of 1, the predicted operation frequency may be determined using the simplified equation:

$${f}_{n + 1}^{′} = {f}_{n} + \frac{{df}_{n}}{dt} ( Δ t ) + ( {f}_{n}^{′} - {f}_{n} )$$

Where no corrective factor has been determined the error coefficient K_{E} may be assigned the value of 0, and this equation may be simplified to:

$${f}_{n + 1}^{′} = {f}_{n} + \frac{{df}_{n}}{dt} ( Δ t )$$

The derivative coefficient K_{D} could be a variable optimised for various market conditions. For example, K_{D} could be set at a value over 1, such as 1.2, to provide additional inertia support when the time derivative determined at step 303 is above an absolute value threshold or below a negative threshold, as in this case the time derivative will be negative as the frequency is falling. K_{D} could be set at a value between 0 and 1, such as 0.8, to provide less inertia support when the time derivative determined at step 303 is below an absolute value threshold or above a negative threshold, as in this case the time derivative will be positive as the frequency is rising. K_{D} could be set at 0 if the time derivative determined at step 303 is close to zero, or if the time derivative is greater than zero while the measured frequency is below the reference operation frequency, corresponding to a time where the frequency is rising after an under-frequency event. Coefficients K_{D} and K_{E} can be dynamic and conditional under market parameters and scenarios.

The predicted operation frequency f′ₙ₊₁ at each time n+1 may be stored in a memory location for later retrieval.

At step 309, the control device 203 determines a frequency difference between the predicted operation frequency f′ₙ₊₁ and a reference operation frequency f_{ref}. The reference operation frequency f_{ref} may be read from a memory storage location in some embodiments. The reference operation frequency f_{ref} may be the primary operation frequency of the electricity grid 101, which may be, for example, 50 Hz in Australia. According to some embodiments, the reference operation frequency f_{ref} may be defined by a range of frequencies, such as by a lower limit and an upper limit of a frequency range which may be an operation frequency range, for example. For example, the lower limit of the frequency band, or the minimum operation frequency of the electricity grid 101, may be 49.85 Hz in Australia. The upper limit of the frequency band, or the maximum operation frequency of the electricity grid 101, may be 50.15 Hz in Australia. Where the reference operation frequency f_{ref} is defined by a range or band of frequencies, the difference between the predicted operation frequency f′ₙ₊₁ and a reference operation frequency f_{ref} may be the smaller of the difference between the predicted operation frequency f′ₙ₊₁ and the upper limit of the reference operation frequency f_{ref}, and the difference between the predicted operation frequency f′ₙ₊₁ and the lower limit of the reference operation frequency f_{ref}. In reality, the operation frequency of the electricity grid 101 almost always fluctuates over time and does not stay at a particular frequency consistently. Therefore, there is almost always a frequency difference between the reference operation frequency and the operation frequency during a particular adjustment interval.

At step 311, the control device 203 instructs the set of grid stabilisation devices 201 to change the collective operation power of the set of grid stabilisation devices 201 based on the determined frequency difference to adjust the operation frequency of the electricity grid.

For example, when the frequency difference indicates the operation frequency is below the reference operation frequency, which means the operation frequency needs to be raised for safety purposes, the control device 203 sends a first command to the set of the grid stabilisation devices 201 instructing the set of grid stabilisation devices 201 to either lower the collective operation power drawn by the grid stabilisation devices 201, or to increase the collective operation power provided by the grid stabilisation devices 201. Where the grid stabilisation devices 201 comprise load devices 220, the control device 203 may issue a command to the grid stabilisation devices 201 that are load devices 220 to lower the collective operation power which they draw from the grid. Where the grid stabilisation devices 201 comprise supply devices 230, the control device 203 may issue a command to the grid stabilisation devices 201 that are supply devices 230 to increase the collective operation power which they supply to the grid.

On the other hand, when the frequency difference indicates the operation frequency is above the reference operation frequency, which means the operation frequency needs to be lowered for safety purposes, the control device 203 sends a second command to the set of grid stabilisation devices 201 instructing the set of grid stabilisation devices 201 to either raise the collective operation power drawn by the grid stabilisation devices 201, or to lower the collective operation power provided by the grid stabilisation devices 201. Where the grid stabilisation devices 201 comprise load devices 220, the control device 203 may issue a command to the grid stabilisation devices 201 that are load devices 220 to raise the collective operation power which they draw from the grid. Where the grid stabilisation devices 201 comprise supply devices 230, the control device 203 may issue a command to the grid stabilisation devices 201 that are supply devices 230 to lower the collective operation power which they supply to the grid.

According to some embodiments, the grid stabilisation devices 201 could include both load devices 220 and supply devices 230. Where the operation frequency needs to be lowered, control device 203 may instruct some or all of the load devices 220 to raise the collective operation power which they draw from the grid, and/or may instruct some or all of the supply devices 230 to lower the collective operation power which they supply to the grid. Where the operation frequency needs to be raised, control device 203 may instruct some or all of the load devices 220 to lower the collective operation power which they draw from the grid, and/or may instruct some or all of the supply devices 230 to raise the collective operation power which they supply to the grid.

In some embodiments, the collective operation power of the grid stabilisation devices 201 could also be altered by changing the amount of power being supplied by grid stabilisation devices 201 which are supply devices 230 to grid stabilisation devices 201 which are load devices 220, for example.

As described above, the set of grid stabilisation devices 201 in the present disclosure can be used as either a load of the electricity grid 101 or a supply to the electricity grid 101 to adjust the operation frequency of the electricity grid 100, depending on whether the grid stabilisation devices 201 comprise load devices 220, supply devices 230, or both. Particularly, power consumption and provision by the set of grid stabilisation devices 201 is controlled on a per device level to adjust the operation frequency of the electricity grid 100. This is particularly advantageous when the electricity system 100 is evolving towards green energy. With the evolution towards green energy, there will be less and less rotor-based power stations (for example, the coal-fired power station 103, the gas power station 105, and the hydroelectric power station 107), which are traditionally used to adjust the operation frequency of the electricity grid 101 by adjusting operation of the rotors in the generators, while there will be more and more invertor-based power stations (for example, solar power plants 109) deployed. The invertor-based power stations do not rely on the rotation of rotors to generate the electricity energy simply because they do not have the rotors (solar power plants generate electricity energy by using solar panels). The above method 300 does not adjust the rotation of any rotors but adjusts the collective operation power of the set of grid stabilisation devices 201 as a load and/or supply of the electricity grid 101. This allows the devices to be more fast-acting than rotor-based power supply devices, allowing real-time control of the operation frequency.

Furthermore, adjusting the collective operation power of the set of grid stabilisation devices 201 can assist in adding a smoothing effect to the electricity supply. This might ordinarily be provided by the inertia of rotor-based power stations, since rotor-based power stations cannot turn on and off rapidly in the manner than inverter-based power stations can. More inverter-based power stations in the grid results in less inertia and more rapid changes in the electricity supply. Such rapid changes require fast acting grid stabilisation devices to avoid undesirable effects to the power supply.

In some embodiments, where the grid stabilisation devices 201 comprise a number of computing devices 2013, each of the individual computing devices 2013 includes a set of chips 2017 designed to perform the one or more computing tasks. For example, the set of chips 2017 can be integrated circuits for central processing units (CPU) or graphics processing units (GPU). The set of chips 2017 of the individual computing devices 2013 is powered by the electricity grid 101 at a chipset power to perform the one or more computing tasks. The electricity energy consumed by the set of chips 2017 normally accounts for a substantial portion of the electricity energy consumed by the individual computing devices 2013. Other parts (for example, the cooling fan) of the computing devices 2013 may consume some electricity energy as well. Therefore, it makes sense to change the individual operation power of the individual computing devices 2013 by changing the chipset power of the set of chips 2017 of the individual computing devices 2013. The sum of the chipset powers of the computing devices 2013 is referred to as a collective chipset power. The collective chipset power of the set of the computing devices 2013 is generally less than the collective operation power of the set of the computing devices 2013. However, if the set of chips 2017 is the only thing that consumes electricity energy in each of the set of computing devices 2013, the collective chipset power is substantially equal to the collective operation power of the set of computing devices 2013. For example, if the computing devices 2013 only have respective set of chips 2017 to provide computing capabilities and a separate cooling system is deployed to cool down the computing devices 2013, then the collective chipset power is substantially equal to the collective operation power of the set of computing devices 2013.

Where the grid stabilisation devices 201 comprise a number of computing devices 2013, the control device 203 may further be configured to instruct at least one of the computing devices 2013 to operate at a different chipset power in order to change the collective operation power of the set of computing devices 2013. Particularly, the control device 203 can send an instruction to at least one of the computing devices 2013 to change frequency-voltage settings of the sets of chips 2017 of the computing device 2013. The changes to the frequency-voltages of the set of chips 2017 causes that computing device 2017 to operate at a different chipset power.

The grid stabilisation network 200 in the present disclosure, which can adjust or control the operation frequency of the electricity grid 101, may provide a load or supply (i.e., the collective operation power) of the order of megawatts (MWs) or gigawatts (GWs), but in some embodiments, only a fraction of the full load or supply may be enabled by the energy market regulator (for example, Australian Energy Market Operator or AEMO in Australia) to adjust the operation frequency of the electricity grid 101. This means the control device 203 may be configured to change the collective operation power of the set of grid stabilisation devices 201 by the enabled power limit at most. The enabled power limit is also referred to as a power change limit in the present disclosure. The power change limit may be less than or equal to the full power load or supply able to be provided by the grid stabilisation network 200.

In some embodiments, the grid stabilisation network 200 is used to raise the operation frequency of the electricity grid 101. In such an embodiment, the reference operation frequency may be the minimum operation frequency as defined by the NOFB, for example, 49.85 Hz in Australia. The control device 203 may be configured to determine the frequency difference as a percentage difference between the predicted operation frequency of the electricity grid 101 during the next adjustment interval and the reference minimum operation frequency, as described above with reference to step 309 of method 300. The control device 203 may also be configured to determine a proportion of the percentage difference to a maximal below percentage, also referred to as a below proportion. The maximal below percentage may be a value defined as the range over which a grid stability device must provide (proportional) grid stability services, and may be a value determined by the energy market operator. The control device 203 may then determine the below proportion multiplied by the power change limit (i.e., the enabled power limit) to be a power reduction value. The power reduction value can be applied as either an increase in load or a decrease in supply. Two examples 1 and 2 are given below to explain how to determine the power reduction value.

### EXAMPLE 1

If the reference minimum operational frequency is 49.85 Hz and the predicted operation frequency of the electricity grid 101 during the next adjustment interval is determined to be 49.35 Hz, then the percentage difference that the operation frequency of the electricity grid 101 is below the reference minimum operation frequency is (49.85−49.35)/49.85=1%. If the maximal below percentage is 2%, as set by the energy market regulator (for example, Australian Energy Market Operator or AEMO in Australia), then the below proportion is (1%)/(2%)=50%. As a result, the power reduction value is 50%×power change limit (i.e., the enabled power limit).

Where the grid stabilisation devices 201 comprise load devices 220, this means the collective operation power drawn by the set of grid stabilisation devices 201 needs to be reduced by 50%×power change limit (i.e., the enabled power limit). Therefore, if the power change limit (or enabled power limit) of the set of grid stabilisation devices 201 is 3 MW, as enabled by the energy market regulator, then the collective operation power drawn by the set of grid stabilisation devices 201 needs to be reduced by 1.5 MW (i.e., 50%×3 MW) in order to raise the operation frequency of the electricity grid 101.

Where the grid stabilisation devices 201 comprise supply devices 230, this means the collective operation power supplied by the set of grid stabilisation devices 201 needs to be increased by 50%×power change limit (i.e., the enabled power limit). Therefore, if the power change limit (or enabled power limit) of the set of grid stabilisation devices 201 is 3 MW, as enabled by the energy market regulator, then the collective operation power supplied by the set of grid stabilisation devices 201 needs to be increased by 1.5 MW (i.e., 50%×3 MW) in order to raise the operation frequency of the electricity grid 101.

### EXAMPLE 2

If the predicted operation frequency of the electricity grid 101 during the next adjustment interval is determined to be 48.85 Hz, then the percentage difference that the predicted operation frequency of the electricity grid 101 is below the reference minimum operation frequency 49.85 Hz is (49.85−48.85)/49.85=2% and the below proportion is (2%)/(2%)=100%. As a result, the power reduction value is 100%×power change limit.

Where the grid stabilisation devices 201 comprise load devices 220, this means the collective operation power of the set of grid stabilisation devices 201 needs to be reduced by 100%×power change limit, or the enabled power limit needs to be completely removed from the set of grid stabilisation devices 201. Therefore, the collective operation power of the set of computing device 201 needs to be reduced by 3 MW (i.e., 100%×3 MW) in order to raise the operation frequency of the electricity grid 101.

Where the grid stabilisation devices 201 comprise supply devices 230, this means the collective operation power of the set of grid stabilisation devices 201 provided to the grid needs to be increased by 100%×power change limit. Therefore, the collective operation power supplied by the grid stabilisation devices 201 needs to be increased by 3 MW (i.e., 100%×3 MW) in order to raise the operation frequency of the electricity grid 101.

As described above, where the grid stabilisation devices 201 comprise computing devices 2013, the collective operation power of the set of grid stabilisation devices 201 can be changed by changing the collective chipset power of the set of computing devices 2013. Particularly, reducing the collective operation power of the set of computing devices 2013 by the power reduction value can be achieved by reducing the collective chipset power of the set of computing devices 2013 by the power reduction value.

There are different ways of reducing the collective chipset power of the set of computing devices 2013. Two examples 3 and 4 are given below without excluding other embodiments.

### EXAMPLE 3

The control device 203, or the control server 213 of the control device 203, maintains a machine register 2018 including machine IDs to identify all the computing devices 2013 in the set of grid stabilisation devices 201, their IP addresses, the individual reserved powers of the set of computing devices 2013 and the cumulative reserved powers. For ease of description, the machine IDs in the machine register 2018 are consecutively numbered, 1, 2, 3, 4 . . . , 758, 759, 760, . . . . The individual reserved powers indicate the amounts of the chipset power that can be reduced or increased from the individual computing devices 2013. The cumulative reserved power for computing device N is the sum of the individual reserved powers of computing devices 1 to N. For example, the cumulative reserved power for computing device 3 is the sum of the individual reserved powers of computing devices 1 to 3, which is 5.5 KW, as shown in the example machine register illustrated below. The IP addresses can be assigned by, for example, the Internet address server 223 according to the Dynamic Host Configuration Protocol (DHCP) that operates on the Internet address server 223. DHCP ensures that IP addresses and their associated leases remain consistent for each computing device 2013. This allows the control server 213 to send TCP or UDP socket instructions to the correct computing devices 2013, and in turn enables the control server 213 to change the power consumption settings of the computing devices 2013 on a per computing device level.

Example Machine Register

| | | Reserved | Cumulative Reserved |
|---|---|---|---|
| Machine ID | IP Address | Power (KW) | Power (KW) |
| 1 | 192.168.0.1 | 1.4 | 1.4 |
| 2 | 192.168.0.2 | 0.8 | 2.2 |
| 3 | 192.168.0.3 | 3.3 | 5.5 |
| 4 | 192.168.0.4 | 2.8 | 8.3 |
| . . . | . . . | . . . | |
| 758 | 192.168.10.13 | 3.6 | 1500 |
| 759 | 192.168.10.14 | 1.6 | 1501.6 |
| 760 | 192.168.10.15 | 1.5 | 1503.1 |
| . . . | . . . | . . . | . . . |

The control device 203 or the control server 213 of the control device 213 can be configured to instruct each of the set of computing devices 2013 to reduce the chipset power of each of the set of computing devices 2013 in order to reduce the collective operation power of the set of computing devices 2013 by the power reduction value. Specifically, the control device 203 determines a proportion of the power reduction value to the collective chipset power of the set of the computing devices 2013, also referred to as a chipset reduction proportion. The control device 203 further instructs each of the set of the computing devices 2013 to reduce the chipset power of each of the set of the computing devices 2013 by the chipset reduction proportion. For example, the control server 213 of the control device 203 sends an instruction via TCP or UDP sockets to each of the set of the computing devices 2013 identified by their respective IP addresses. In response to receipt of the instruction, each of the set of computing devices 2013 reduces its chipset power by the chipset reduction proportion according to, for example, their respective internal Application Programming Interface (API). This way, the collective operation power of the set of computing devices 2013 can be reduced by the power reduction value.

In the above Example 1, where the grid stabilisation devices 201 are load devices 220, the power reduction value is 1.5 MW. If the set of computing devices 2013 are operating at a collective chipset power of 35 MW during the adjustment interval, then chipset reduction proportion is 1.5 MW/35 MW=4.3%. This means the control device 203 instructs each of the set of the computing devices 2013 to reduce the chipset power of each of the set of the computing devices 2012 by 4.3% by changing their frequency-voltage settings. As a result, the collective operation power of the set of the computing devices 2013 is reduced by 1.5 MW.

In the above Example 2, where the grid stabilisation devices 201 are load devices 220, the power reduction value is 3 MW, then chipset reduction proportion is 3 MW/35 MW=8.6%. This means the control device 203 instructs each of the set of the computing devices 2013 to reduce the chipset power of each of the set of computing devices 2013 by 8.6 % by changing their frequency-voltage settings. As a result, the collective operation power of the set of computing devices 2013 is reduced by 3 MW.

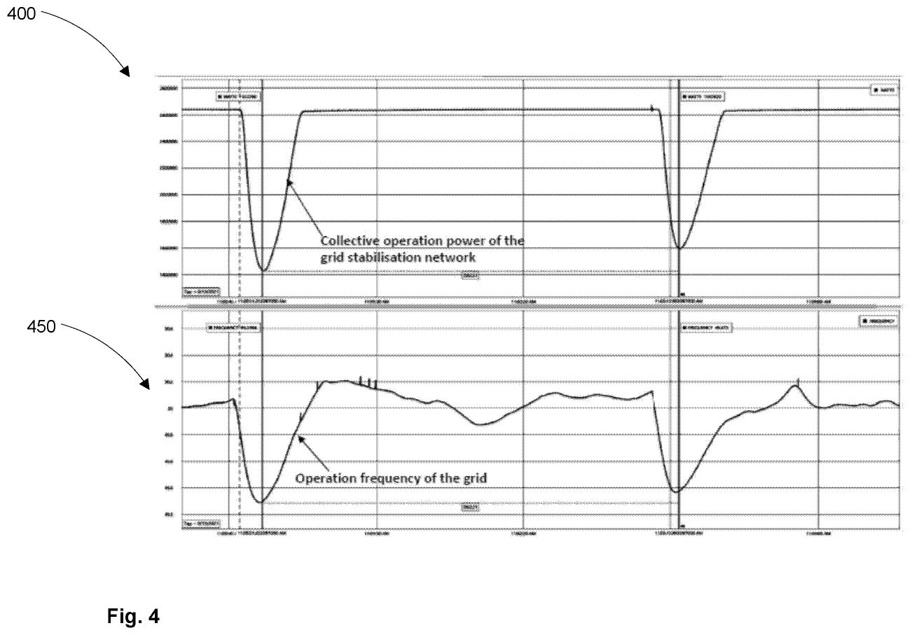

FIG. 4 shows graphs 400 and 450 illustrating the fluctuation of the operation power of the set of grid stabilisation devices 201 in response to the fluctuation of the operation frequency of the electricity grid 101 in accordance with Example 3. In graph 400, the x-axis shows a time, while the y-axis shows a power in watts of the grid. In graph 450, the x-axis shows a time, while the y-axis shows a frequency of the grid.

### EXAMPLE 4

In the above Example 3, the control device 203 instructs each of the set of the computing devices 2013 to reduce their chipset powers. The process described in Example 3 will become less responsive if the set of computing devices 2013 include many computing devices, say as many as 25,000 or even more computing devices, because it takes more time to send the instruction to 25,000 or more computing devices and for the 25,000 or more computing devices to change their voltage-frequency settings. In Example 4, the control device 203 is configured to instruct some (not all) of the computing devices 2013 to reduce the chipset power of each of those computing devices 2013 in order to reduce the collective operation power of the set of computing devices 2013 by the power reduction value.

An exemplary method of determining the subset of the set of computing devices in Example 4 is provided below.

In the above Example 1, where the grid stabilisation devices 201 are load devices 220, the power reduction value is 1.5 MW. This means that the collective chipset power of the set of the computing devices 2013 needs to be reduced by 1.5 MW. The control device 203 or the control server 213 of the control device 203 searches the machine register 2018 for a cumulative reserved power of 1.5 MW (i.e., 1500 KW). The Machine ID that correspond to 1.5 MW is 758. Therefore, the control device 203 determines that computing devices 1 to 758 are the subset of the set of computing devices 2013. As a result, the control device 203 sends an instruction to the computing devices 1 to 758 to reduce their chipset powers by the corresponding individual reserved powers, respectively. For example, the control server 213 of the control device 203 sends an instruction via TCP or UDP sockets to each of the subset of the set of the computing devices 2013 identified by their respective IP addresses, from 192.168.0.1 (Machine ID: 1) to 192.168.10.13 (Machine ID: 758). In response to receipt of the instruction, each of the subset of the set of computing devices 2013 reduces its chipset power by its corresponding individual reserved power according to, for example, their respective internal Application Programming Interface (API). This way, the collective chipset power of the set of computing devices is reduced by the power reduction value of 1.5 MW, and thus the collective operation power of the set of computing devices is reduced by the power reduction value of 1.5 MW.

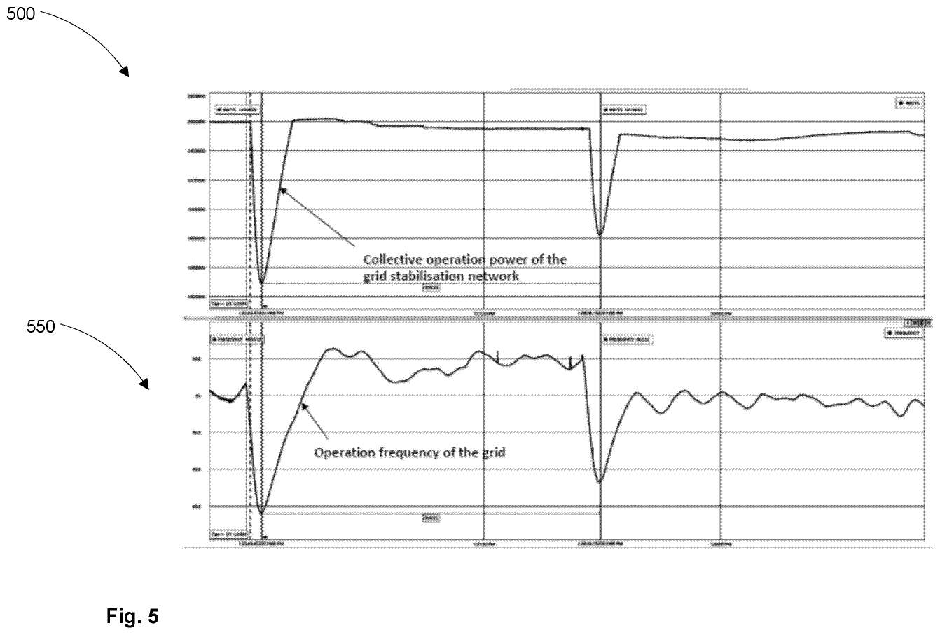

FIG. 5 shows graphs 500 and 550 illustrating the fluctuation of the operation power of the set of grid stabilisation devices 201 in response to the fluctuation of the operation frequency of the electricity grid 101 in accordance with Example 4. In graph 500, the x-axis shows a time, while the y-axis shows a power in watts of the grid. In graph 550, the x-axis shows a time, while the y-axis shows a frequency of the grid.

In some embodiments, the grid stabilisation network 200 is used to lower the operation frequency of the electricity grid 101. In this embodiment, the reference operation frequency is the maximum operation frequency, for example, 50.15 Hz in Australia. The control device 203 is configured to determine the frequency difference as a percentage difference that the operation frequency of the electricity grid 101 during the adjustment interval is above the maximum operation frequency. The control device 203 also determines a proportion of the percentage difference to a maximal above percentage, referred to as an above proportion hereinafter. The control device 203 then determines the above proportion times the power change limit (i.e., the enabled power limit) to be a power increase value. Two examples 5 and 6 are given below to explain how to determine the power increase value.

### EXAMPLE 5

If the reference maximum operational frequency is 49.85 Hz and the predicted operation frequency of the electricity grid 101 during the next adjustment interval is predicted to be 50.65 Hz, then the percentage difference between the predicted operation frequency of the electricity grid 101 and the reference maximum operation frequency 50.15 Hz is (50.65−50.15)/50.15=1%. If the maximal above percentage is 2%, as set by the energy market regulator (for example, Australian Energy Market Operator or AEMO in Australia), then the above proportion is (1%)/(2%)=50%. As a result, the power increase value is 50%×power change limit (i.e., the enabled power limit).

Where the grid stabilisation devices 201 comprise load devices 220, this means the collective operation power drawn by the set of grid stabilisation devices 201 needs to be increased by 50%×power change limit (i.e., the enabled power limit). Therefore, if the power change limit (or enabled power limit) of the set of grid stabilisation devices 201 is 3 MW, as enabled by the energy market regulator, then the collective operation power drawn by the set of grid stabilisation devices 201 needs to be increased by 1.5 MW (i.e., 50%×3 MW) in order to lower the operation frequency of the electricity grid 101.

Where the grid stabilisation devices 201 comprise supply devices 230, this means the collective operation power supplied by the set of grid stabilisation devices 201 needs to be decreased by 50%×power change limit (i.e., the enabled power limit). Therefore, if the power change limit (or enabled power limit) of the set of grid stabilisation devices 201 is 3 MW, as enabled by the energy market regulator, then the collective operation power supplied by the set of grid stabilisation devices 201 needs to be decreased by 1.5 MW (i.e., 50%×3 MW) in order to lower the operation frequency of the electricity grid 101.

### EXAMPLE 6

If the predicted operation frequency of the electricity grid 101 during the next adjustment interval is 51.15 Hz, then the percentage difference between the predicted operation frequency of the electricity grid 101 and the reference maximum operation frequency 50.15 Hz is (51.15−50.15)/50.15=2% and the above proportion is (2%)/(2%)=100%. As a result, the power increase value is 100%×power change limit.

Where the grid stabilisation devices 201 comprise load devices 220, this means the collective operation power drawn by the set of grid stabilisation devices 201 needs to be increased by 100%×power change limit, or the enabled power limit needs to be fully added to the set of grid stabilisation devices 201. Therefore, the collective operation power drawn by the set of grid stabilisation devices 201 needs to be increased by 3 MW (i.e., 100%×3MW) in order to lower the operation frequency of the electricity grid 101.

Where the grid stabilisation devices 201 comprise supply devices 230, this means the collective operation power supplied by the set of grid stabilisation devices 201 needs to be decreased by 100%×power change limit, or the power supplied by the grid stabilisation devices 201 needs to be completely removed. Therefore, the collective operation power supplied by the set of grid stabilisation devices 201 needs to be decreased by 3 MW (i.e., 100%×3 MW) in order to lower the operation frequency of the electricity grid 101.

As described above, where the grid stabilisation devices 201 are computing devices 2013, the collective operation power of the set of the computing devices 2013 can be changed by changing the collective chipset power of the set of the computing devices 2013. Particularly, increasing the collective operation power of the set of the computing devices 2013 by the power increase value can be achieved by increasing the collective chipset power of the set of the computing devices 2013 by the power increase value.

There are different ways of increasing the collective chipset power of the set of the computing devices 2013. Two examples 7 and 8 are given below without excluding other embodiments.

### EXAMPLE 7

The control device 203 can be configured to instruct each of the set of computing devices 2013 to increase the chipset power of each of the set of computing devices 2013 in order to increase the collective operation power of the set of computing devices 2013 by the power increase value. Specifically, the control device 203 determines a proportion of the power increase value to the collective chipset power of the set of computing devices 2013, referred to as a chipset increase proportion hereinafter. The control device 203 further instructs each of the set of computing devices 2013 to increase the chipset power of each of the set of computing devices 2013 by the chipset increase proportion. For example, the control server 213 of the control device 203 sends an instruction via TCP or UDP sockets to each of the set of computing devices 2013 identified by their respective IP addresses. In response to receipt of the instruction, each of the set of computing devices 2013 increases its chipset power by the chipset increase proportion according to, for example, their respective internal Application Programming Interface (API). This way, the collective operation power of the set of computing devices 2013 can be increased by the power increase value.

In the above Example 5, where the grid stabilisation devices 201 are load devices 220, the power increase value is 1.5 MW. If the set of computing devices 2013 are operating at a collective chipset power of 35 MW during the adjustment interval, then the chipset increase proportion is 1.5 MW/35 MW=4.3%. Then the control device 203 instructs each of the set of computing devices 2013 to increase the chipset power of each of the set of computing devices by 4.3% by changing their frequency-voltage settings. As a result, the collective operation power of the set of computing devices 2013 is increased by 1.5 MW.

In the above Example 6, where the grid stabilisation devices 201 are load devices 220, the power increase value is 3 MW, then the chipset increase proportion is 3 MW/35 MW=8.6%. The control device 203 instructs each of the set of computing devices 2013 to increase the chipset power of each of the set of computing devices 2013 by 8.6% by changing their frequency-voltage settings. As a result, the collective operation power of the set of computing devices 2013 is increased by 3 MW.

### EXAMPLE 8

In the above Example 7, the control device 203 instructs each of the set of computing device 2013 to increase their chipset powers. The process described in Example 7 will become less responsive if the set of computing device 2013 include many computing devices, say as many as 25,000 or even more computing devices, because it takes more time to send the instruction to 25,000 or more computing devices and for the 25,000 or more computing devices to change their voltage-frequency settings. In Example 8, the control device 203 is configured to instruct some (not all) of the computing devices 2013 to increase the chipset power of each of those computing devices 2013 in order to increase the collective operation power of the set of computing devices 2013 by the power increase value.

An exemplary method of determining the subset of the set of computing devices 2013 in Example 8 is provided below.

In the above Example 5, where the grid stabilisation devices 201 are load devices 220, the power increase value is 1.5 MW. This means that the collective chipset power of the set of the computing devices 2013 needs to be increased by 1.5 MW. The control device 203 or the control server 213 of the control device 203 searches the machine register 2018 for a cumulative reserved power of 1.5 MW (i.e., 1500 KW). The Machine ID that correspond to 1.5 MW is 758. Therefore, the control device 203 determines that computing devices 1 to 758 are the subset of the set of computing devices 2013. As a result, the control device 203 sends an instruction to the computing devices 1 to 758 to increase their chipset powers by the corresponding individual reserved powers, respectively. For example, the control server 213 of the control device 203 sends an instruction via TCP or UDP sockets to each of the subset of the set of computing devices 2013 identified by their respective IP addresses, from 192.168.0.1 (Machine ID: 1) to 192.168.10.13 (Machine ID: 758). In response to receipt of the instruction, each of the subset of the set of computing devices 2013 increases its chipset power by its corresponding individual reserved power according to, for example, their respective internal Application Programming Interface (API). This way, the collective chipset power of the set of computing devices 2013 is increased by the power increase value of 1.5 MW, and thus the collective operation power of the set of computing devices 2013 is increased by the power increase value of 1.5 MW.

FIG. 6 illustrates an exemplary structure of the control device 203 in accordance with some embodiments.

As shown in FIG. 6, the control device 203 comprises a processor 2031, a bus 2033, a computer-readable memory 2035, a first communication interface 2037, and a second communication interface 2039. The processor 2031 is connected to the computer-readable memory 2035, the first communication interface 2037, and the second communication interface 2039 via the bus 2033. Therefore, the processor 2031 is able receive instructions and/or data from these components and send the instructions and/or data to these components. The processor 2031 is one of, but not limited to, a general-purpose processor, an application specific integrated circuit (ASIC) and a field-programmable gate array (FPGA). The computer-readable memory 2035 is configured to store a set of computer-readable instructions. The computer-readable instructions can be written in a computer-programming language, for example, Python. The first communication interface 2037 is configured to connect to the set of grid stabilisation devices 201 via the communication link 7 as shown in FIG. 2, while the second communication interface 2039 is configured to connect to the frequency reader 205 via the communication link 8 as shown in FIG. 2.

The processor 2031 is configured to read the computer-readable instructions from the computer-readable memory 2035 and execute the computer-readable instructions to perform the method steps as described above.

In accordance with another embodiment of the present invention, the computer-readable instructions are made available on a non-transitory computer-readable medium. The non-transitory computer-readable medium, may be, but not limited to Read-Only Memory (ROM), Random Access Memory (RAM), Electrically Erasable Programmable Read-Only Memory (EEPROM), CD-ROM, DVD-ROM, Flash Drive, a cloud storage unit, a File Transport Protocol (FTP) server, etc. The set of computer-readable instructions may be loaded in a form of a computer software program into the computer-readable memory 2035. When executed by the processor 2031 of the control device 203, the control device 203 may perform the method steps of method 300 or 350 as described above.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is meant to provide the broadest scope, consistent with the principles and the novel and inventive features disclosed or suggested herein. Accordingly, the disclosure is anticipated to hold on to all other such alternatives, modifications, and variations that fall within the scope of the present disclosure and appended claims.

1.-25. (canceled)

26. A computer-implemented method for adjusting an operation frequency of an electricity grid, the electricity grid electrically connecting to at least one grid stabilisation device, the method comprising, at a control device:
obtaining from a frequency reader connected to the electricity grid the operation frequency of the electricity grid during an adjustment interval;
determining a time derivative of the obtained operation frequency;
determining a predicted future operation frequency based on the obtained operation frequency and the time derivative;
determining a frequency difference between the predicted future operation frequency and a reference operation frequency; and
instructing the at least one grid stabilisation device to change its collective operation power to adjust the operation frequency of the electricity grid.

27. The method of claim 1, further comprising determining a prediction error, the prediction error being a difference between the obtained operation frequency and a previously predicted operation frequency.

28. The method of claim 1, wherein determining a predicted future operation frequency comprises adjusting the predicted future operation frequency by the prediction error.

29. The method of claim 1, wherein the at least one grid stabilisation device comprises at least one load device.

30. The method of claim 29, wherein instructing the at least one grid stabilisation device to change its collective operation power comprises instructing the at least one load device to increase the amount of power it is drawing from the grid.

31. The method of claim 29, wherein instructing the at least one grid stabilisation device to change its collective operation power comprises instructing the at least one load device to decrease the amount of power it is drawing from the grid.

32. The method of claim 26, wherein the at least one grid stabilisation device comprises at least one supply device.

33. The method of claim 32, wherein instructing the at least one grid stabilisation device to change its collective operation power comprises instructing the at least one supply device to increase the amount of power it is supplying to the grid.

34. The method of claim 32, wherein instructing the at least one grid stabilisation device to change its collective operation power comprises instructing the at least one supply device to decrease the amount of power it is supplying to the grid.

35. A computer-implemented method for adjusting an operation frequency of an electricity grid, the electricity grid electrically connecting to at least one grid stabilisation device, the method comprising, at a control device:
obtaining from a frequency reader connected to the electricity grid the operation frequency of the electricity grid during an adjustment interval;
determining a frequency difference between the obtained operation frequency and a reference operation frequency; and
instructing the at least one grid stabilisation device to change its collective operation power to adjust the operation frequency of the electricity grid by altering the power being supplied by the at least one grid stabilisation device to the grid;
wherein the control device does not affect the operation of any rotor-based grid stabilisation devices.

36. The method of claim 35, wherein the at least one grid stabilisation device comprises at least one supply device.

37. The method of claim 36, wherein the at least one grid stabilisation device comprises a power generation device.

38. The method of claim 15, wherein the at least one grid stabilisation device comprises at least one power storage device.

39. The method of claim 38, wherein the at least one grid stabilisation device comprises a battery.

40. The method of claim 35, wherein instructing the at least one grid stabilisation device to change its collective operation power comprises instructing the at least one supply device to increase the amount of power it is supplying to the grid.

41. The method of claim 35, wherein instructing the at least one grid stabilisation device to change its collective operation power comprises instructing the at least one supply device to decrease the amount of power it is supplying to the grid.

42. The method of claim 26, wherein the at least one grid stabilisation device is at least one of:
a non-rotor based device;
an inverter-based device; and
a battery.

43. The method of claim 35, wherein the at least one grid stabilisation device is at least one of:
a non-rotor based device;
an inverter-based device; and
a battery.

44. An electric load network for adjusting an operation frequency of an electricity grid in real time, the electric load network comprising:
a set of grid stabilisation devices;
a control device that is connected to the set of grid stabilisation devices;
a frequency reader that is connected to the control device, the frequency reader being configured to read from the electricity grid the operation frequency of the electricity grid during an adjustment interval;
wherein the control device is configured to
obtain from the frequency reader the operation frequency of the electricity grid during an adjustment interval;
determine a time derivative of the obtained operation frequency;
determine a predicted future operation frequency based on the obtained operation frequency and the time derivative;
determine, a frequency difference between the predicted future operation frequency and a reference operation frequency; and
instruct the grid stabilisation devices to change their collective operation power to adjust the operation frequency of the electricity grid.

45. An electric load network for adjusting an operation frequency of an electricity grid in real time, the electric load network comprising:
a set of grid stabilisation devices;
a control device that is connected to the set of grid stabilisation devices;
a frequency reader that is connected to the control device, the frequency reader being configured to read from the electricity grid the operation frequency of the electricity grid during an adjustment interval;
wherein the control device is configured to
obtain from the frequency reader the operation frequency of the electricity grid during an adjustment interval;
determine a frequency difference between the obtained operation frequency and a reference operation frequency; and
instruct the grid stabilisation devices to change their collective operation power to adjust the operation frequency of the electricity grid by altering the power being supplied by the at least one grid stabilisation device to the grid;
wherein the control device does not affect the operation of any rotor-based grid stabilisation devices.
